(19) United States
(12) Patent Application Publication
(10) Pub. No.: US 2026/0190555 A1
(43) Pub. Date: Jul. 2, 2026

(54) Display Device

(71) Applicant: LG Display Co., Ltd., Seoul (KR)

(72) Inventors: Yong-Ku Lee, Gimbo-si (KR); ARa Yoon, Seoul (KR); DaeHeung Lee, Paju-si (KR); JinWoo Hong, Seoul (KR); YoungBok Lee, Paju-si (KR)

(21) Appl. No.: 19/412,353

(22) Filed: Dec. 8, 2025

(30) Foreign Application Priority Data
Dec. 30, 2024 (KR) 10-2024-0200155

(51) Int. Cl. H10H 20/855; H10H 29/37

(52) U.S. Cl. CPC H10H 20/855; H10H 29/37

(57) ABSTRACT

The disclosure relates to a display device. The display device according to an aspect of the present disclosure includes a substrate, a light emitting diode disposed on the substrate and including a first electrode, an emission layer, and a second electrode, a bank disposed on the substrate to cover an end of the first electrode and to define an emission area, and an optical member disposed on the light emitting diode and having a bar shape extending in a first direction. The emission area includes a first emission area extending in the first direction and a plurality of second emission areas protruding in a second direction from the first emission area.

### CROSS-REFERENCE TO RELATED APPLICATION

This application claims priority to Republic of Korea Patent Application No. 10-2024-0200155 filed on Dec. 30, 2024, which is incorporated by reference.

### TECHNICAL FIELD

The present disclosure relates to a display device, and more particularly, to a display device in which a luminance difference according to a viewing angle between a degraded emission area and a non-degraded emission area is reduced.

### BACKGROUND

As technology advances in modern society, display devices are being widely used to provide information to users. Display devices are included not only in electric signboards that simply transmit visual information in a one-way manner, but also in various electronic devices that require more advanced technology, which recognize user inputs and provide information in response to the recognized inputs.

For example, a display device may be included in a vehicle to provide various information to a driver and passengers. However, the display device of the vehicle needs to appropriately display content so as not to interfere with the operation of the vehicle. For instance, during driving the vehicle, the display device may need to restrict the display of content that could reduce the driver's concentration on driving.

### SUMMARY

An object to be achieved by the present disclosure is to provide a display device capable of limiting a vertical viewing angle.

Another object to be achieved by the present disclosure is to provide a display device capable of suppressing reflection of an image on a structure located outside the display device.

Still another object to be achieved by the present disclosure is to provide a display device in which luminance difference according to a viewing angle between a degraded emission area and a non-degraded emission area is reduced.

Objects of the present disclosure are not limited to the above-mentioned objects, and other objects, which are not mentioned above, can be clearly understood by those skilled in the art from the following descriptions.

A display device according to an aspect of the present disclosure comprises a substrate, a light emitting diode disposed on the substrate and including a first electrode, an emission layer, and a second electrode, a bank disposed on the substrate to cover an end of the first electrode and to define an emission area, and an optical member disposed on the light emitting diode and having a bar shape extending in a first direction, wherein the emission area includes a first emission area extending in the first direction and a plurality of second emission areas protruding in a second direction from the first emission area.

A display device according to another aspect of the present dosclosure comprises a substrate on which a plurality of sub pixels each including an emission area is defined, a plurality of light emitting diodes disposed on the substrate in each of the plurality of sub pixels and including a first electrode, an emission layer, and a second electrode, a bank disposed on the substrate to cover an end of the first electrode and to define the emission area, and a plurality of optical members disposed on the plurality of light emitting diodes and having a bar shape extending in a first direction, wherein the emission area includes a plurality of protrusions and a plurality of recesses alternately disposed at each of opposite ends in a second direction.

Other detailed matters of the embodiments of the present disclosure are included in the detailed description and the drawings.

The present disclosure may suppress an image from being reflected and recognized on a structure located above the display device by limiting a vertical viewing angle.

The present disclosure may reduce luminance difference according to a viewing angle between a degraded emission area and a non-degraded emission area.

The present disclosure may provide higher-quality images at various viewing angles regardless of the degree of degradation.

The effects of the present disclosure are not limited to the aforementioned effects, and other effects, which are not mentioned above, will be apparently understood to a person having ordinary skill in the art from the following description.

The effects according to the present disclosure are not limited to the contents exemplified above, and more various effects are included in the present specification.

### BRIEF DESCRIPTION OF THE DRAWINGS

The above and other aspects, features and other advantages of the present disclosure will be more clearly understood from the following detailed description taken in conjunction with the accompanying drawings, in which:

FIG. 1 is a view of a display device according to one or more embodiments of the present disclosure.

FIG. 2 is a functional block diagram of a display device according to one or more embodiments of the present disclosure.

FIG. 3 is an enlarged plan view of a pixel included in a display device according to one or more embodiments of the present disclosure;

FIG. 4 is a cross-sectional view taken along line IV-IV′ of FIG. 3.

FIG. 5 is an enlarged plan view of a pixel included in a display device according to one or more embodiments of the present disclosure.

FIG. 6A is a graph illustrating results of a luminance difference experiment according to one or more embodiments of the present disclosure.

FIG. 6B is a graph illustrating results of a luminance difference experiment of a display device according to one or more embodiments of the present disclosure.

### DETAILED DESCRIPTION

Advantages and characteristics of the present disclosure and a method of achieving the advantages and characteristics will be clear by referring to embodiments described below in detail together with the accompanying drawings. However, the present disclosure is not limited to the embodiments disclosed herein but will be implemented in various forms. The embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the embodiments of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “comprising” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly”.

When an element or layer is disposed “on” another element or layer, another layer or another element may be interposed directly on the other element or therebetween.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, a display device according to embodiments of the present disclosure will be described in detail with reference to accompanying drawings.

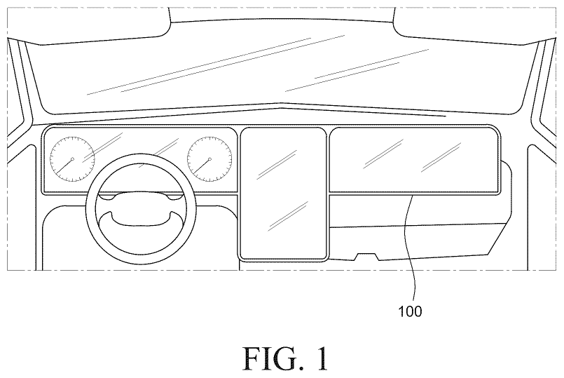

FIG. 1 is a view of a display device according to one or more embodiments of the present disclosure.

Referring to FIG. 1, the display device 100 may be disposed on at least a portion of the dashboard of a vehicle. The dashboard of the vehicle may include a configuration disposed in front of a front seat (e.g., a driver's seat and a passenger's seat) of the vehicle. For example, the dashboard of the vehicle may include an input configuration for operating various functions (e.g., an air conditioner, an audio system, and a navigation system) inside the vehicle.

The display device 100 may operate as an input unit disposed on the dashboard of the vehicle to operate at least some of various functions of the vehicle. The display device 100 may provide various information related to the vehicle, for example, driving information of the vehicle (e.g., a current speed of the vehicle, a remaining fuel amount, and a travel distance) and information about parts of the vehicle (e.g., a damage degree of a vehicle tire).

The display device 100 may be disposed to extend across the driver's seat and the passenger's seat disposed in the front seat of the vehicle. Users of the display device 100 may include both a driver and a passenger seated in the passenger's seat. Both the driver and the passenger may use the display device 100.

The display device 100 illustrated in FIG. 1 may represent only a part thereof. The display device 100 illustrated in FIG. 1 may represent a display panel among various configurations included in the display device 100. Specifically, for example, the display device 100 illustrated in FIG. 1 may represent at least a portion of an active area and a non-active area of the display panel. Configurations other than the portion illustrated in FIG. 1 among the configurations of the display device 100 may be mounted inside the vehicle (or at least a portion thereof).

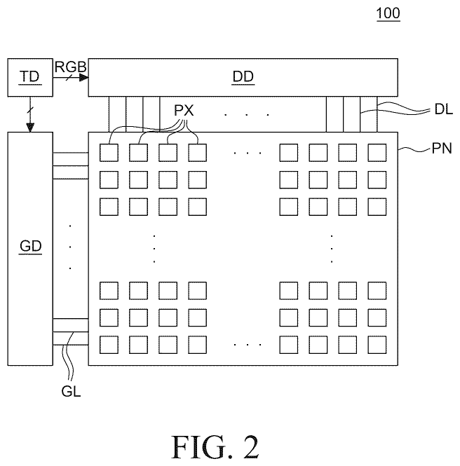

FIG. 2 is a functional block diagram of a display device according to one or more embodiments of the present disclosure.

The display device according to one or more embodiments of the present disclosure may employ an electroluminescent display device. The electroluminescent display device may include an organic light emitting diode display device, a quantum-dot light emitting diode display device, or an inorganic light emitting diode display device.

Referring to FIG. 2, the display device 100 may include a display panel PN, a data driving circuit DD, a gate driving circuit GD, and a timing controller TD.

The display panel PN may generate an image to be provided to a user. For example, the display panel PN may generate and display an image to be provided to the user through a plurality of pixels PX, each having a pixel circuit disposed therein.

The data driving circuit DD, the gate driving circuit GD, and the timing controller TD may provide signals for operation of each pixel PX through signal lines. For example, the signal lines for providing signals for operation of each pixel PX may include a plurality of data lines DL and a plurality of gate lines GL.

The plurality of data lines DL may be disposed in a column direction and may include a plurality of wiring lines connected to the pixels PX disposed in one column direction, and the plurality of gate lines GL may be disposed in a row direction and may include a plurality of wiring lines connected to the pixels PX disposed in one row direction.

In some cases, the display device 100 may further include a power supply unit. In such a case, a signal for operation of each pixel PX may be provided through a power line connecting the power supply unit and the display panel PN. In some embodiments, the power supply unit may provide power to the data driving circuit DD and the gate driving circuit GD. The data driving circuit DD and the gate driving circuit GD may operate based on the power supplied from the power supply unit.

For example, the data driving circuit DD may apply a data signal to each pixel PX through the plurality of data lines DL, the gate driving circuit GD may apply a gate signal to each pixel PX through the plurality of gate lines GL, and the power supply unit may supply a power voltage to each pixel PX through a power voltage supply line.

The timing controller TD may control the data driving circuit DD and the gate driving circuit GD. For example, the timing controller TD may rearrange digital video data input from the outside to match a resolution of the display panel PN and may supply the rearranged data to the data driving circuit DD.

The data driving circuit DD may convert the digital video data input from the timing controller TD into an analog data voltage based on a data control signal and may supply the analog data voltage to the plurality of data lines DL.

The gate driving circuit GD may generate a scan signal and an emission signal based on a gate control signal. For example, the gate driving circuit GD may include a scan driver and an emission signal driver. The scan driver may generate the scan signal in a row sequential manner to drive at least one scan line connected to each pixel row, and may supply the scan signal to the scan lines. The emission signal driver may generate the emission signal in a row sequential manner to drive at least one emission signal line connected to each pixel row, and may supply the emission signal to the emission signal lines.

In some embodiments, the gate driving circuit GD may be disposed on the display panel PN in a gate-driver in panel (GIP) manner. For example, the gate driving circuit GD may be divided into a plurality and may be disposed on each of at least two sides of the display panel PN.

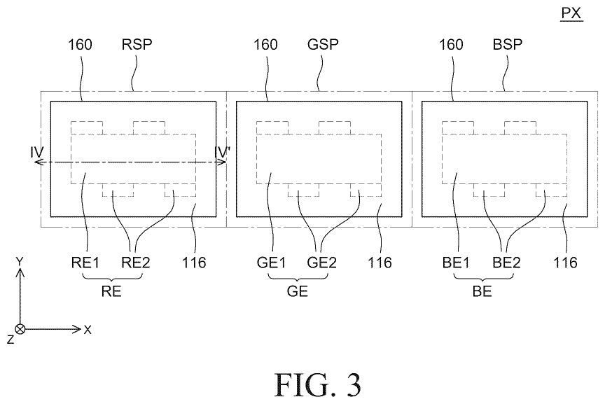

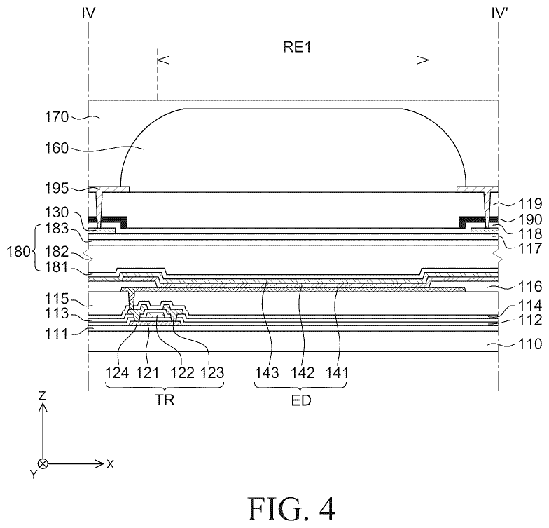

FIG. 3 is an enlarged plan view of a pixel included in a display device according to one or more embodiments of the present disclosure. FIG. 4 is a cross-sectional view taken along line IV-IV′ of FIG. 3.

Meanwhile, FIG. 3 illustrates a plane of a pixel PX in a case where the pixel PX includes three sub pixels, for example, a first sub pixel RSP, a second sub pixel GSP, and a third sub pixel BSP.

In addition, FIG. 4 illustrates, as an embodiment of the display device 100 taken along line IV-IV′ of FIG. 3, a pixel in which an optical member 160 is disposed.

Meanwhile, in FIG. 4, for convenience of explanation, only an area corresponding to the first sub pixel RSP among the three sub pixels RSP, GSP, and BSP illustrated in FIG. 3 is illustrated. However, the other sub pixels GSP and BSP may also be formed in the same configuration.

Meanwhile, for convenience of explanation, in the following description, a horizontal direction on a plane is referred to as a first direction X, and a vertical direction on the plane is referred to as a second direction Y. In addition, a normal direction of a plane defined by the first direction X and the second direction Y, for example, a thickness direction of the display device 100, may be defined as a third direction Z.

Referring to FIG. 3, the pixel PX may include a plurality of sub pixels RSP, GSP, and BSP that represent different colors. For example, the pixel PX may include the first sub pixel RSP that implements red, the second sub pixel GSP that implements green, and the third sub pixel BSP that implements blue. In some embodiments, the first sub pixel RSP may be referred to as a red sub pixel, the second sub pixel GSP as a green sub pixel, and the third sub pixel BSP as a blue sub pixel. A pixel circuit may be disposed in each of the plurality of sub pixels RSP, GSP, and BSP included in the pixel PX.

In one pixel PX, each of the sub pixels RSP, GSP, and BSP may be sequentially disposed in the first direction. For example, in one pixel PX, the first sub pixel RSP, the second sub pixel GSP, and the third sub pixel BSP may be sequentially disposed in the first direction X, but is not limited thereto. A disposition order of the sub pixels RSP, GSP, and BSP in one pixel PX may be changed as needed. In addition, in one pixel PX, each of the sub pixels RSP, GSP, and BSP may also be disposed in the second direction.

Each of the sub pixels RSP, GSP, and BSP may include at least one optical member 160 disposed to overlap a corresponding emission area RE, GE, or BE. The emission areas RE, GE, and BE and the optical member 160 may have a shape extending in the first direction X. For example, a width of the optical member 160 in the first direction X may be greater than a width thereof in the second direction Y. Also, a maximum width of the emission areas RE, GE, and BE in the first direction X may be greater than a maximum width thereof in the second direction Y. Accordingly, a viewing angle of the display device 100 in the first direction X may be greater than that in the second direction Y.

Referring also to FIG. 4, the display device 100 according to one or more embodiments of the present disclosure may include a substrate 110, a buffer film 111, a gate insulating film 112, a first interlayer insulating film 113, a lower protective film 114, an overcoat layer 115, a bank 116, a transistor TR, a light emitting diode ED, an encapsulation member 180, a second interlayer insulating film 118, a black matrix 190, a touch electrode 195, an optical member 160, and an optical member protective film 170.

The substrate 110 may include an insulating material. The substrate 110 may include a transparent material. For example, the substrate 110 may include glass or plastic.

The buffer film 111 may be disposed on the substrate 110. The buffer film 111 may include an insulating material. For example, the buffer film 111 may include an inorganic insulating material such as silicon oxide (SiOx) and silicon nitride (SiNx). The buffer film 111 may have a multilayer structure. For example, the buffer film 111 may have a laminated structure including a film made of silicon nitride (SiNx) and a film made of silicon oxide (SiOx).

The buffer film 111 may be located between the substrate 110 and a driving portion of each of the sub pixels RSP, GSP, and BSP. The buffer film 111 may suppress contamination by the substrate 110 during a process of forming the driving portion. For example, a top surface of the substrate 110 facing the driving portion of each of the sub pixels RSP, GSP, and BSP may be covered by the buffer film 111. The driving portion of each of the sub pixels RSP, GSP, and BSP may be located on the buffer film 111.

The gate insulating film 112 may be disposed on the buffer film 111. The gate insulating film 112 may include an insulating material. For example, the gate insulating film 112 may include an inorganic insulating material such as silicon oxide (SiOx) and silicon nitride (SiNx). The gate insulating film 112 may include a material having a high dielectric constant. For example, the gate insulating film 112 may include a high-k material such as hafnium oxide (HfO). The gate insulating film 112 may have a multilayer structure.

The first interlayer insulating film 113 may be disposed on the gate insulating film 112. The first interlayer insulating film 113 may include an insulating material. For example, the first interlayer insulating film 113 may include an inorganic insulating material such as silicon oxide (SiOx) and silicon nitride (SiNx). The first interlayer insulating film 113 may extend between a gate electrode 122 and a source electrode 123 of the transistor TR, and between the gate electrode 122 and a drain electrode 124. For example, the source electrode 123 and the drain electrode 124 of the transistor TR may be insulated from the gate electrode 122 by the first interlayer insulating film 113. The first interlayer insulating film 113 may cover the gate electrode 122 of the transistor TR. The source electrode 123 and the drain electrode 124 of each of the sub pixels RSP, GSP, and BSP may be located on the first interlayer insulating film 113. The gate insulating film 112 and the first interlayer insulating film 113 may expose source and drain areas of each semiconductor layer 121 located in each of the sub pixels RSP, GSP, and BSP.

The lower protective film 114 may be disposed on the first interlayer insulating film 113. The lower protective film 114 may include an insulating material. For example, the lower protective film 114 may include an inorganic insulating material such as silicon oxide (SiOx) and silicon nitride (SiNx).

The lower protective film 114 may suppress damage to the driving portion caused by moisture and impact from the outside. The lower protective film 114 may extend along a surface of the transistor TR. The lower protective film 114 may contact the first interlayer insulating film 113 at an outer side of the driving portion located in each of the sub pixels RSP, GSP, and BSP.

The overcoat layer 115 may be disposed on the lower protective film 114. The overcoat layer 115 may include an insulating material. The overcoat layer 115 may include a material different from that of the lower protective film 114. For example, the overcoat layer 115 may include an organic insulating material.

The overcoat layer 115 may eliminate a step caused by the driving portion of each of the sub pixels RSP, GSP, and BSP. For example, a top surface of the overcoat layer 115 far away from, rather than near to, the substrate 110 may be a flat surface.

The transistor TR may be disposed on the substrate 110. the drain electrode of the transistor TR may be electrically connected with a first electrode 141 of the light emitting diode ED.

The transistor TR may include a semiconductor layer 121, the gate electrode 122, the source electrode 123, and the drain electrode 124.

For example, the semiconductor layer 121 may be located between the buffer film 111 and the gate insulating film 112, and the gate electrode 122 may be located between the gate insulating film 112 and the first interlayer insulating film 113. The source electrode 123 and the drain electrode 124 may be located between the first interlayer insulating film 113 and the lower protective film 114. The gate electrode 122 may overlap a channel area of the semiconductor layer 121. The source electrode 123 may be electrically connected to a source area of the semiconductor layer 121. The drain electrode 124 may be electrically connected to a drain area of the semiconductor layer 121.

The light emitting diode ED of each of the sub pixels RSP, GSP, and BSP may be disposed on the overcoat layer 115 of the corresponding sub pixel RSP, GSP, or BSP. For example, the first electrode 141 of the light emitting diode ED may be electrically connected to the drain electrode 124 or the source electrode 123 of the transistor TR through a contact hole penetrating the lower protective film 114 and the overcoat layer 115.

The light emitting diode ED may emit light representing a specific color. For example, the light emitting diode ED may include the first electrode 141, an emission layer 142, and a second electrode 143 sequentially laminated on the substrate 110.

The first electrode 141 may include a conductive material. The first electrode 141 may include a material having high reflectivity. For example, the first electrode 141 may include a metal such as aluminum (Al) and silver (Ag). The first electrode 141 may have a multilayer structure. For example, the first electrode 141 may have a structure in which a reflective electrode made of metal is located between transparent electrodes made of a transparent conductive material such as indium tin oxide (ITO) and indium zinc oxide (IZO). The first electrode 141 may be electrically connected to the drain electrode 124 of the transistor TR through a contact hole penetrating the lower protective film 114 and the overcoat layer 115.

The emission layer 142 may generate light having luminance corresponding to a voltage difference between the first electrode 141 and the second electrode 143. For example, the emission layer 142 may include an emission material layer (EML) including an emission material. The emission material may include an organic material, an inorganic material, or a hybrid material.

The emission layer 142 may have a multilayer structure. For example, the emission layer 142 may further include at least one of a hole injection layer (HIL), a hole transport layer (HTL), an electron transport layer (ETL), and an electron injection layer (EIL).

The second electrode 143 may include a conductive material. The second electrode 143 may include a material different from that of the first electrode 141. A transmittance of the second electrode 143 may be greater than a transmittance of the first electrode 141. For example, the second electrode 143 may be a transparent electrode made of a transparent conductive material such as ITO and IZO. Accordingly, in the display device 100 according to one or more embodiments of the present disclosure, light generated by the emission layer 142 may be emitted through the second electrode 143. The second electrodes 143 of the respective sub pixels RSP, GSP, and BSP may be spaced apart from one another. For example, the bank 116 may be disposed between the first electrodes 141 of the respective sub pixels RSP, GSP, and BSP. The bank 116 may include an insulating material. For example, the bank 116 may include an organic insulating material. The bank 116 may include a material different from that of the overcoat layer 115.

The bank 116 may be disposed to cover ends of the first electrodes 141 located in the respective sub pixels RSP, GSP, and BSP. Accordingly, the first electrodes 141 of the respective sub pixels RSP, GSP, and BSP may be insulated from one another by the bank 116.

The bank 116 defines the emission areas RE, GE, and BE of the light emitting diode ED. For example, the emission areas RE, GE, and BE of the light emitting diode ED may be portions of areas where the first electrode 141 is disposed and which are exposed by the bank 116.

Referring also to FIG. 3, each of the emission areas RE, GE, and BE may include a first emission area RE1, GE1, or BE1 extending in the first direction X, and a plurality of second emission areas RE2, GE2, and BE2 protruding in the second direction Y from the first emission area RE1, GE1, or BE1.

The first emission areas RE1, GE1, and BE1 may be central areas of the respective emission areas RE, GE, and BE. The first emission areas RE1, GE1, and BE1 may have a bar shape extending in the first direction X. Accordingly, a width of the first emission areas RE1, GE1, and BE1 in the first direction X may be greater than a width thereof in the second direction Y.

The plurality of second emission areas RE2, GE2, and BE2 may be respectively disposed at both ends of the first emission areas RE1, GE1, and BE1. For example, the plurality of second emission areas RE2, GE2, and BE2 may be disposed at both ends of the first emission areas RE1, GE1, and BE1 in the second direction Y.

The plurality of second emission areas RE2, GE2, and BE2 may be disposed at one end of the first emission areas RE1, GE1, and BE1. In this case, the plurality of second emission areas RE2, GE2, and BE2 may be disposed spaced apart from one another. For example, referring to FIG. 3, at an upper end of the first emission areas RE1, GE1, and BE1, a protrusion including the plurality of second emission areas RE2, GE2, and BE2 and a recess formed by spacing the plurality of second emission areas RE2, GE2, and BE2 apart from one another may be disposed.

The plurality of second emission areas RE2, GE2, and BE2 may be disposed at the other end opposite to the one end of the first emission areas RE1, GE1, and BE1. In this case, the plurality of second emission areas RE2, GE2, and BE2 may be disposed spaced apart from one another. For example, referring to FIG. 3, at a lower end of the first emission areas RE1, GE1, and BE1, a protrusion including the plurality of second emission areas RE2, GE2, and BE2 and a recess formed by spacing the plurality of second emission areas RE2, GE2, and BE2 apart from one another may be disposed.

The plurality of second emission areas RE2, GE2, and BE2 protruding from one end of the first emission areas RE1, GE1, and BE1 may be alternately disposed with the plurality of second emission areas RE2, GE2, and BE2 protruding from the other end. For example, referring to FIG. 3, the plurality of second emission areas RE2, GE2, and BE2 respectively disposed at the upper and lower ends of the first emission areas RE1, GE1, and BE1 may not face each other.

The plurality of second emission areas RE2, GE2, and BE2 disposed at one end of the first emission areas RE1, GE1, and BE1 may be disposed to face areas spaced apart from the plurality of second emission areas RE2, GE2, and BE2 disposed at the other end. The plurality of second emission areas RE2, GE2, and BE2 disposed at both ends of the first emission areas RE1, GE1, and BE1 may be disposed not to overlap each other in the second direction Y. For example, referring to FIG. 3, the plurality of second emission areas RE2, GE2, and BE2, which are protrusions disposed at the upper ends of the first emission areas RE1, GE1, and BE1, may be disposed to face recesses disposed at the lower ends.

The bank 116 may be disposed between the plurality of second emission areas RE2, GE2, and BE2. For example, referring to FIG. 3, the bank 116 may be disposed in areas where the plurality of second emission areas RE2, GE2, and BE2 is spaced apart from one another. Accordingly, the bank 116 may be disposed to enclose the first emission areas RE1, GE1, and BE1 and the second emission areas RE2, GE2, and BE2.

An outer contour of the plurality of second emission areas RE2, GE2, and BE2 may include a plurality of first straight portions extending in the second direction Y from one end of the first emission areas RE1, GE1, and BE1, and a second straight portion connecting the plurality of first straight portions. In this case, the second straight portion may be parallel to the first direction X. For example, referring to FIG. 3, the plurality of second emission areas RE2, GE2, and BE2 may have a rectangular shape, but is not limited thereto.

At one end of the first emission areas RE1, GE1, and BE1, a total length of the second straight portions may be in a range of 30% to 70% of a width of the first emission areas RE1, GE1, and BE1 in the first direction X. For example, referring to FIG. 3, at one end of the first emission areas RE1, GE1, and BE1, the total length of the second straight portions of the plurality of second emission areas RE2, GE2, and BE2 may be half of the width of the first emission areas RE1, GE1, and BE1 in the first direction X, but is not limited thereto. In addition, a length of the first straight portion of the plurality of second emission areas RE2, GE2, and BE2 may be smaller than a width of the first emission areas RE1, GE1, and BE1 in the second direction Y.

A size of the plurality of second emission areas RE2, GE2, and BE2 may be uniform, but is not limited thereto. For example, the length of each of the first straight portion and the second straight portion of the plurality of second emission areas RE2, GE2, and BE2 may all be the same, but is not limited thereto.

A total length of the second straight portions of the plurality of second emission areas RE2, GE2, and BE2 disposed at one end of the first emission areas RE1, GE1, and BE1 and a total length of the second straight portions of the plurality of second emission areas RE2, GE2, and BE2 disposed at the other end may be the same.

A width of the emission area RE, GE, or BE in the second direction Y may be uniform. In this case, the width of the emission area RE, GE, or BE in the second direction Y may refer to a distance from one end of the first light emission area RE1, GE1, or BE1 to one end of a facing second emission area RE2, GE2, or BE2.

The emission layer 142 and the second electrode 143 of the light emitting diode ED located in each of the sub pixels RSP, GSP, and BSP may be laminated on a portion of the first electrode 141 exposed by the bank 116. Specifically, the emission layer 142 and the second electrode 143 may be laminated on the first emission area RE1, GE1, or BE1 exposed by the bank 116 and the bank 116.

An encapsulation member 180 may be located on the light emitting diode ED of each of the sub pixels RSP, GSP, and BSP. The encapsulation member 180 may suppress damage to the light emitting diode ED caused by moisture and impact from the outside. The encapsulation member 180 may have a multilayer structure. For example, the encapsulation member 180 may include a first encapsulation layer 181, a second encapsulation layer 182, and a third encapsulation layer 183 which are laminated in order, but is not limited thereto.

The first encapsulation layer 181, the second encapsulation layer 182, and the third encapsulation layer 183 may include an insulating material. The second encapsulation layer 182 may include a material different from those of the first encapsulation layer 181 and the third encapsulation layer 183. For example, the first encapsulation layer 181 and the third encapsulation layer 183 may be inorganic encapsulation layers including an inorganic insulating material, and the second encapsulation layer 182 may be an organic encapsulation layer including an organic insulating material. Accordingly, the light emitting diode ED of the display device 100 may be more effectively protected from damage caused by moisture and impact from the outside.

A touch buffer layer 117 may be disposed on the encapsulation member 180. The t ouch buffer layer 117 may be disposed between the encapsulation member 180 and a touch bridge electrode 130 to insulate the touch bridge electrode 130. For example, the touch buffer layer 117 may include an insulating material. For example, the touch buffer layer 117 may be formed of an organic insulating material or an inorganic insulating material, but is not limited thereto.

The touch bridge electrode 130 may be disposed on the touch buffer layer 117. The touch bridge electrode 130 may electrically connect touch electrodes 195 on a second interlayer insulating film 118. For example, the touch bridge electrode 130 may include a metal material such as titanium (Ti), aluminum (Al), silver (Ag), copper (Cu), or a magnesium-silver alloy (Mg:Ag), but is not limited thereto.

The second interlayer insulating film 118 may be disposed on the touch bridge electrode 130. The second interlayer insulating film 118 may be disposed between the touch bridge electrode 130 and a black matrix 190 to insulate the touch bridge electrode 130. The second interlayer insulating film 118 may include an insulating material. For example, the second interlayer insulating film 118 may include an organic insulating material or an inorganic insulating material, but is not limited thereto.

The black matrix 190 may be disposed on the second interlayer insulating film 118. The black matrix 190 may be disposed between the plurality of sub pixels RSP, GSP, and BSP to reduce color mixing between the plurality of sub pixels RSP, GSP, and BSP. Accordingly, the black matrix 190 may be disposed to overlap the bank 116.

A third interlayer insulating film 119 may be disposed on the black matrix 190. The third interlayer insulating film 119 may include an insulating material. For example, the third interlayer insulating film 119 may include an organic insulating material or an inorganic insulating material, but is not limited thereto.

A plurality of touch electrodes 195 may be located on the third interlayer insulating film 119. The plurality of touch electrodes 195 may be disposed above a first light emitting diode ED1 and a second light emitting diode ED2 in an active area. The plurality of touch electrodes 195 may be disposed on the third interlayer insulating film 119 to be spaced apart from one another.

The plurality of touch electrodes 195 may be configured to sense an external touch input using a user's finger or a touch pen. For example, each touch electrode TE may include a metal material such as titanium (Ti), aluminum (Al), silver (Ag), copper (Cu), or a magnesium-silver alloy (Mg:Ag), but is not limited thereto.

The plurality of touch electrodes 195 may be disposed to overlap the bank 116 and the black matrix 190. In addition, when the plurality of touch electrodes 195 includes an opaque metal material, the plurality of touch electrodes 195 may also serve as a barrier layer that limits a path of light generated by the light emitting diode ED. For example, the plurality of touch electrodes 195 may block light traveling in a lateral direction among light emitted from the emission areas RE, GE, and BE. That is, the plurality of touch electrodes 195 may block light traveling in a lateral direction among light emitted from first emission areas RE1, GE1, and BE1 and second emission areas RE2, GE2, and BE2 located in each of the sub pixels RSP, GSP, and BSP, for example, together with the black matrix 190 or the bank 116, but is not limited thereto.

The optical member 160 may be disposed on the third interlayer insulating film 119.

The optical member 160 may be disposed on the third interlayer insulating film 119 in the same layer as the plurality of touch electrodes 195. For example, the optical member 160 may be disposed to cover edges of the plurality of touch electrodes 195. Accordingly, an end of the optical member 160 may be located on the plurality of touch electrodes 195.

In this case, a center of the optical member 160 may coincide with a center of the emission areas RE, GE, and BE, but is not limited thereto.

The optical member 160 may be disposed on the light emitting diode ED. Light generated by the light emitting diode ED of each of the sub pixels RSP, GSP, and BSP may be emitted through the optical member 160.

The optical member 160 may have a shape that does not limit light traveling in at least one direction. A planar shape of the optical member 160 may be a shape extending in the first direction X. Specifically, the planar shape of the optical member 160 may be a bar shape extending in the first direction X. Accordingly, the planar shape of the optical member 160 may include a long side extending in the first direction X and a short side extending from both ends of the long side in the second direction Y. For example, the planar shape of the optical member 160 may be a rectangle with the long side placed in the first direction X.

In this case, a traveling direction of light emitted from the emission areas RE, GE, and BE of each of the sub pixels RSP, GSP, and BSP may not be limited to the first direction X. For example, content provided by light emitted through the optical member 160 may be provided at a wide viewing angle in the first direction X.

On the other hand, a width of the optical member 160 in the second direction Y may be smaller than a width thereof in the first direction X. Accordingly, light emitted from the emission areas RE, GE, and BE of each of the sub pixels RSP, GSP, and BSP may be limited in traveling in the second direction Y. For example, content provided by light emitted through the optical member 160 may be provided at a narrower viewing angle in the second direction Y than in the first direction X.

At least a portion of a top surface of a cross-sectional shape of the optical member 160 taken in the first direction X may be flat. In addition, both side surfaces of the optical member 160 may be formed of curves or straight lines. For example, referring to FIG. 4, a cross-sectional shape of the optical member 160 based on the long side may be formed of an upper flat surface and curves extending from both ends of the flat surface toward the third interlayer insulating film 119. Alternatively, for example, a cross-sectional shape of the optical member 160 based on the long side may be formed of an upper flat surface and straight lines extending vertically from both ends of the flat surface toward the third interlayer insulating film 119.

The optical member 160 may have a size larger than that of the emission areas RE, GE, and BE of the corresponding sub pixel RSP, GSP, or BSP. Accordingly, an efficiency of light emitted from the emission areas RE, GE, and BE of each of the sub pixels RSP, GSP, and BSP may be improved.

Although not illustrated in the drawings, an organic or inorganic insulating layer may be further disposed between the plurality of touch electrodes 195 and the optical member 160, but is not limited thereto.

An optical member protective film 170 may be located on the optical member 160. The optical member protective film 170 may include an insulating material. For example, the optical member protective film 170 may include an organic insulating material. A refractive index of the optical member protective film 170 may be smaller than a refractive index of the optical member 160. Accordingly, light passing through the optical member 160 may not be reflected toward the substrate 110 due to a difference in refractive index with the optical member protective film 170.

Meanwhile, when the display device is disposed on at least a portion of the dashboard of a vehicle to provide content to a user, for example, a driver and a passenger, the display device may be located generally below a frontal line of sight of the user. In addition, a structure such as a windshield may be disposed above the display device. Accordingly, content emitted from the display device may be reflected by the structure disposed above the display device. When an image emitted from the display device is reflected by an external structure in this way, both the image emitted from the display device and the reflected image may be visually recognized by the user, thereby lowering visibility of the image and possibly disturbing the driver's driving.

Accordingly, in the display device 100 according to one or more embodiments of the present disclosure, the emission areas RE, GE, and BE and the optical member 160 may have a shape extending in the first direction X, for example, in a left-right direction with respect to the user. Therefore, the display device 100 may have a narrower viewing angle in the second direction Y, for example, in an up-down direction with respect to the user, than in the first direction X. In this way, the display device 100 according to one or more embodiments of the present disclosure may suppress reflection of the image by an upper structure by limiting the viewing angle in the second direction Y. Accordingly, visibility of the display device 100 may be improved.

When the display device is repeatedly driven, a predetermined amount of heat may be generated in the light emitting diode of the display device. When heat continues to be generated in the light emitting diode in this way, degradation may occur in some of the light emitting diodes. As the light emitting diode degrades, an emission area of the degraded light emitting diode may shrink. However, degradation may not occur in all of the light emitting diodes. For example, in some of the light emitting diodes, degradation may occur and the emission area may shrink, while in other light emitting diodes, degradation may not occur and the emission area may not shrink. In addition, when a degree of degradation varies between the light emitting diodes, a degree of shrinkage of the emission area may also vary between the light emitting diodes. As such, when the degree of degradation varies between the light emitting diodes, sizes of the emission areas may become different between the light emitting diodes, resulting in a luminance difference between areas.

Accordingly, in the display device 100 according to one or more embodiments of the present disclosure, the emission areas RE, GE, and BE may include the first emission areas RE1, GE1, and BE1 extending in the first direction X, and the plurality of second emission areas RE2, GE2, and BE2 protruding from both ends of the first emission areas RE1, GE1, and BE1 in the second direction Y. As such, since the plurality of second emission areas RE2, GE2, and BE2 protrudes relatively outward, even if they shrink due to degradation, they may still remain relatively protruded. As a result, a difference in area between the non-degraded emission areas RE, GE, and BE and the degraded emission areas RE, GE, and BE at both ends in the second direction Y may be relatively reduced.

Specifically, when the emission area is formed only of a bar shape extending in the first direction X, ends of the emission area in the second direction may overall shrink due to degradation, thereby causing a large difference in area between the non-degraded emission areas and the degraded emission areas at the ends in the second direction. In contrast, since the display device 100 according to one or more embodiments of the present disclosure includes the plurality of second emission areas RE2, GE2, and BE2 protruding from the first emission areas RE1, GE1, and BE1, even if degradation occurs, the protruding second emission areas RE2, GE2, and BE2 may still maintain a protruded shape. Therefore, a difference in area between the ends of the non-degraded emission areas RE, GE, and BE and the ends of the degraded emission areas RE, GE, and BE may be relatively reduced.

As the difference in area between the ends of the non-degraded emission areas RE, GE, and BE and the degraded emission areas RE, GE, and BE decreases in this way, a luminance difference according to the viewing angle in the second direction Y between the non-degraded emission areas RE, GE, and BE and the emission areas RE, GE, and BE after degradation may be reduced.

By way of another example, the display device 100 according to one or more embodiments of the present disclosure may include the plurality of protruding second emission areas RE2, GE2, and BE2, so that each of the emission areas RE, GE, and BE may have a different light profile. Taking the emission area RE of the first sub pixel RSP as an example, the emission area RE of the first sub pixel RSP may include the plurality of second emission areas RE2 disposed so as not to face each other at both ends in the second direction Y. Accordingly, in an area where the second emission area RE2 protruding upward is disposed, the light profile may be formed to be biased upward with respect to a center of the first emission area RE1. In contrast, in an area where the second emission area RE2 protruding downward is disposed, the light profile may be formed to be biased downward with respect to the center of the first emission area RE1. By complementing each other in this way, the differently formed light profiles may reduce the luminance difference between the degraded emission areas RE, GE, and BE and the non-degraded emission areas RE, GE, and BE.

Accordingly, the display device 100 according to one or more embodiments of the present disclosure may suppress a pattern such as a stain from being visually recognized due to a luminance difference between the non-degraded emission areas RE, GE, and BE and the emission areas RE, GE, and BE after degradation. Therefore, the display device 100 according to one or more embodiments of the present disclosure may provide higher-quality images at various viewing angles regardless of a degree of degradation.

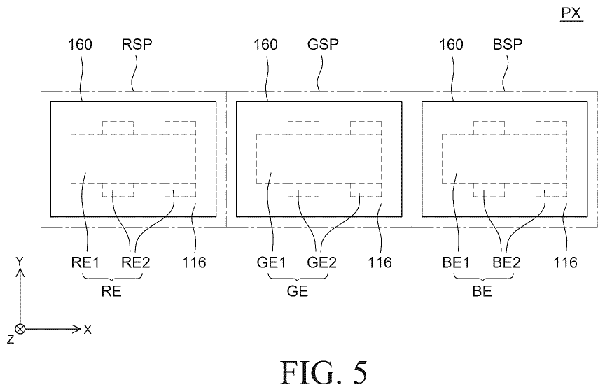

FIG. 5 is an enlarged plan view of a pixel included in a display device according to one or more embodiments of the present disclosure.

The display device illustrated in FIG. 5 differs from the display device 100 of FIGS. 1 to 4 only in a planar shape of the emission areas RE, GE, and BE, and other configurations are substantially the same, so a repeated description thereof will be omitted.

In the display device according to one or more embodiments of the present disclosure, the emission areas RE, GE, and BE may include the first emission areas RE1, GE1, and BE1 having a planar shape extending in the first direction X, and the plurality of second emission areas RE2, GE2, and BE2 extending in the second direction Y from both ends of the first emission areas RE1, GE1, and BE1.

The first emission areas RE1, GE1, and BE1 may be central areas of the respective emission areas RE, GE, and BE. The first emission areas RE1, GE1, and BE1 may have a bar shape extending in the first direction X. Accordingly, a width of the first emission areas RE1, GE1, and BE1 in the first direction X may be greater than a width thereof in the second direction Y.

The plurality of second emission areas RE2, GE2, and BE2 may be respectively disposed at both ends of the first emission areas RE1, GE1, and BE1. For example, the plurality of second emission areas RE2, GE2, and BE2 may be disposed at both ends of the first emission areas RE1, GE1, and BE1 in the second direction Y.

The plurality of second emission areas RE2, GE2, and BE2 may be disposed at one end of the first emission areas RE1, GE1, and BE1. In this case, the plurality of second emission areas RE2, GE2, and BE2 may be disposed spaced apart from one another. For example, referring to FIG. 5, at an upper end of the first emission areas RE1, GE1, and BE1, a protrusion including the plurality of second emission areas RE2, GE2, and BE2 and a recess formed by spacing the plurality of second emission areas RE2, GE2, and BE2 apart from one another may be alternately disposed.

The plurality of second emission areas RE2, GE2, and BE2 may be disposed at the other end opposite to the one end of the first emission areas RE1, GE1, and BE1. In this case, the plurality of second emission areas RE2, GE2, and BE2 may be disposed spaced apart from one another. For example, referring to FIG. 5, at a lower end of the first emission areas RE1, GE1, and BE1, a protrusion including the plurality of second emission areas RE2, GE2, and BE2 and a recess formed by spacing the plurality of second emission areas RE2, GE2, and BE2 apart from one another may be alternately disposed.

The plurality of second emission areas RE2, GE2, and BE2 protruding from one end of the first emission areas RE1, GE1, and BE1 may be disposed to face the plurality of second emission areas RE2, GE2, and BE2 protruding from the other end. For example, referring to FIG. 5, the plurality of second emission areas RE2, GE2, and BE2 respectively disposed at the upper and lower ends of the first emission areas RE1, GE1, and BE1 may be disposed to face each other. In addition, recesses disposed at one end of the first emission areas RE1, GE1, and BE1 may be disposed to face recesses disposed at the other end.

Accordingly, the emission areas RE, GE, and BE may include at least two areas having different widths in the second direction Y. For example, referring to FIG. 5, the emission areas RE, GE, and BE may include a first area in which the second emission areas RE2, GE2, and BE2 disposed at the upper end face the second emission areas RE2, GE2, and BE2 disposed at the lower end, and a second area in which a recess disposed at the upper end faces a recess disposed at the lower end. In this case, a width of the first area in the second direction Y may be greater than a width of the second area.

The bank 116 may be disposed between the plurality of second emission areas RE2, GE2, and BE2. For example, referring to FIG. 5, the bank 116 may be disposed in areas where the plurality of second emission areas RE2, GE2, and BE2 is spaced apart from one another. Accordingly, the bank 116 may be disposed to enclose the first emission areas RE1, GE1, and BE1 and the second emission areas RE2, GE2, and BE2.

An outer contour of the plurality of second emission areas RE2, GE2, and BE2 may include a plurality of first straight portions extending in the second direction Y from one end of the first emission areas RE1, GE1, and BE1, and a second straight portion connecting the plurality of first straight portions. In this case, the second straight portion may be parallel to the first direction X. For example, referring to FIG. 5, the plurality of second emission areas RE2, GE2, and BE2 may have a rectangular shape, but is not limited thereto.

At one end of the first emission areas RE1, GE1, and BE1, a total length of the second straight portions may be in a range of 30% to 70% of a width of the first emission areas RE1, GE1, and BE1 in the first direction X. For example, referring to FIG. 5, at one end of the first emission areas RE1, GE1, and BE1, the total length of the second straight portions of the plurality of second emission areas RE2, GE2, and BE2 may be half of the width of the first emission areas RE1, GE1, and BE1 in the first direction X, but is not limited thereto. In addition, a length of the first straight portion of the plurality of second emission areas RE2, GE2, and BE2 may be smaller than a width of the first emission areas RE1, GE1, and BE1 in the second direction Y.

A size of the plurality of second emission areas RE2, GE2, and BE2 may be uniform, but is not limited thereto. For example, lengths of the first straight portion and the second straight portion of each of the plurality of second emission areas RE2, GE2, and BE2 may all be the same, but is not limited thereto.

A total length of the second straight portions of the plurality of second emission areas RE2, GE2, and BE2 disposed at one end of the first emission areas RE1, GE1, and BE1 and a total length of the second straight portions of the plurality of second emission areas RE2, GE2, and BE2 disposed at the other end may be the same.

As such, the display device according to one or more embodiments of the present disclosure may have the emission areas RE, GE, and BE and the optical member 160 having a shape extending in the first direction X, for example, in a left-right direction with respect to a user. By limiting a viewing angle in the second direction Y, reflection of an image by an upper structure may be suppressed. In addition, visibility of the display device may be further improved.

Furthermore, in the display device according to one or more embodiments of the present disclosure, the emission areas RE, GE, and BE may include the first emission areas RE1, GE1, and BE1 extending in the first direction X, and the plurality of second emission areas RE2, GE2, and BE2 protruding from both ends of the first emission areas RE1, GE1, and BE1 in the second direction Y. The plurality of second emission areas RE2, GE2, and BE2 disposed at both ends of the first emission areas RE1, GE1, and BE1 may be disposed to face each other. Accordingly, since the plurality of second emission areas RE2, GE2, and BE2 protrudes relatively outward, even if the emission areas RE, GE, and BE shrink due to degradation, they may still remain relatively protruded.

Therefore, a difference in area between the non-degraded emission areas RE, GE, and BE and the degraded emission areas RE, GE, and BE at both ends in the second direction Y may be relatively more reduced.

As the difference in area between the ends of the non-degraded emission areas RE, GE, and BE and the degraded emission areas RE, GE, and BE decreases in this way, a luminance difference according to the viewing angle in the second direction Y between the non-degraded emission areas RE, GE, and BE and the emission areas RE, GE, and BE after degradation may be further reduced.

By way of another example, in a display device according to one or more embodiments of the present disclosure, the emission areas RE, GE, and BE may include at least two areas having different widths in the second direction Y, so that each of the emission areas RE, GE, and BE may have a different light profile. Taking the emission area RE of the first sub pixel RSP as an example, the emission area RE of the first sub pixel RSP may include a first area in which a second emission area RE2 disposed at an upper end and a second emission area RE2 disposed at a lower end face each other, and a second area in which the second emission area RE2 is not disposed at either an upper end or at a lower end. In this case, since the first area is an area in which the second emission area RE2 extending in the second direction Y is disposed, its width in the second direction Y may be greater than that of the second area in which the second emission area RE2 is not disposed. Accordingly, in the first area of the emission area RE, a wider light profile in the second direction Y may be formed. In contrast, in the second area, a light profile having a width in the second direction that is relatively smaller than that of the first area may be formed.

Thus, since different light profiles are formed in each emission area RE, GE, or BE, even if the emission area is reduced due to degradation, the wide light profile of the first area and the narrow light profile of the second area may complement each other. Accordingly, the luminance difference between the degraded emission areas RE, GE, and BE and the non-degraded emission areas RE, GE, and BE may be further reduced.

Accordingly, the display device according to one or more embodiments of the present disclosure may suppress a pattern such as a stain from being visually recognized due to a luminance difference between the non-degraded emission areas RE, GE, and BE and the emission areas RE, GE, and BE after degradation. Therefore, the display device according to one or more embodiments of the present disclosure may provide high-quality images at various viewing angles regardless of the degree of degradation.

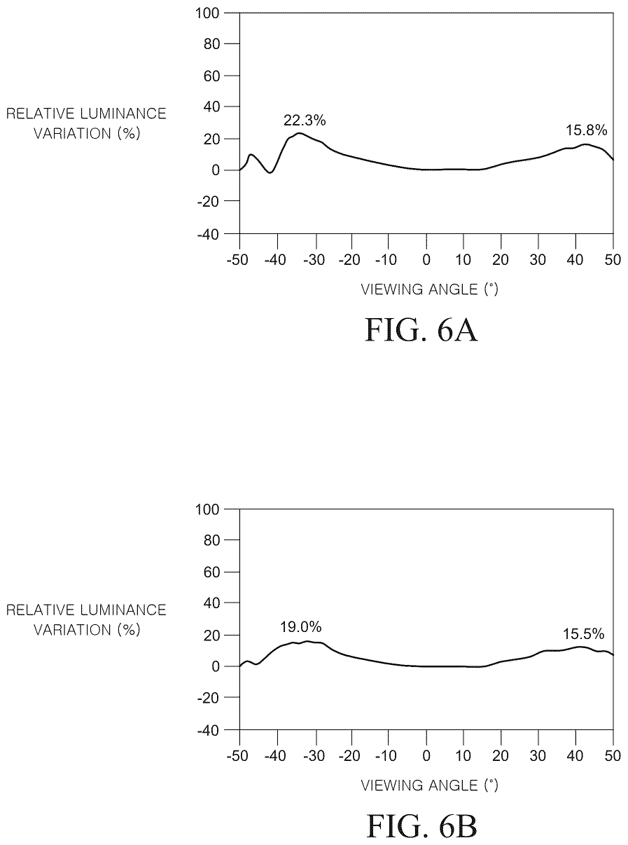

Meanwhile, in order to describe the effects of the display device according to one or more embodiments of the present disclosure in more detail, a description will be given hereinafter with reference to FIGS. 6A and 6B.

FIG. 6A is a graph illustrating results of a luminance difference experiment according to one or more embodiments of the present disclosure. FIG. 6B is a graph illustrating results of a luminance difference experiment of a display device according to one or more embodiments of the present disclosure.

Specifically, FIGS. 6A and 6B respectively illustrate a comparison in which the luminance value of a non-degraded emission area and the luminance value of the emission area after degradation are measured for the display devices of one or more embodiments of the present disclosure. In this case, a front compensation is performed in which the luminance difference occurring between the non-degraded emission area and the emission area after degradation in a front direction, that is, at a viewing angle of 0°, is corrected to 0. Then, based on the luminance value of the non-degraded emission area, a variation rate of the luminance value of the emission area after degradation is calculated and converted into a percentage (%), and illustrates. Here, the emission area after degradation refers to the emission area formed when the light emitting diode is driven at a brightness of 800 nits at a temperature of 65° C. for 1,500 hours.

First, referring to FIG. 6A, FIG. 6A is a graph illustrating experimental results of the one or more embodiments of the present disclosure. In this case, the one or more embodiments refer to a display device that does not include any separate emission area protruding in the second direction Y but includes only an emission area in a bar shape extending in the first direction X. In the front direction where the viewing angle is 0°, there is no change in luminance between the emission area before and after degradation because front compensation is performed in the experimental process. In contrast, in the upper viewing angle, the luminance before and after degradation can be found to differ by up to about 15.8%, and in the lower viewing angle, the luminance before and after degradation can be found to differ by up to about 22.3%. It can be confirmed that even if front compensation is performed, a luminance difference occurs between the emission area before degradation and the emission area after degradation in peripheral viewing angles.

Next, referring to FIG. 6B, FIG. 6B is a graph illustrating experimental results of one or more embodiments of the present disclosure. When a plurality of emission areas RE2, GE2, and BE2 protruding in a second direction Y2 and a third direction Y3 are disposed at both ends of the first emission areas RE1, GE1, and BE1 extending in a first direction X, as in one or more embodiments of the present disclosure, it can be confirmed that the luminance before and after degradation differed by up to about 15.5% in an upper viewing angle. As such, compared with the embodiment of FIG. 6A, the display device according to one or more embodiments of the present disclosure illustrates a reduced luminance difference between the emission areas before and after degradation in the upper viewing angle. In addition, in a lower viewing angle, it can be confirmed that the luminance before and after degradation differed by up to about 19.0%. As such, compared with the comparative example of FIG. 6A, the display device according to one or more embodiments of the present disclosure illustrates a reduced luminance difference between the emission areas before and after degradation in the lower viewing angle.

Accordingly, the display device according to one or more embodiments of the present disclosure exhibits a reduced luminance difference between the emission areas before and after degradation in a peripheral viewing angle compared with the comparative embodiment.

The embodiments of the present disclosure can also be described as follows:

A display device according to an aspect of the present disclosure comprises a substrate, a light emitting diode disposed on the substrate and including a first electrode, an emission layer, and a second electrode, a bank disposed on the substrate to cover an end of the first electrode and to define an emission area, and an optical member disposed on the light emitting diode and having a bar shape extending in a first direction, wherein the emission area includes a first emission area extending in the first direction and a plurality of second emission areas protruding in a second direction from the first emission area.

The plurality of second emission areas protruding from one end of the first emission area may be alternately disposed with the plurality of second emission areas protruding from the other end of the first emission area.

A width of an entirety of the emission area including the first emission area and the plurality of second emission areas in the second direction may be uniform.

The plurality of second emission areas protruding from one end of the first emission area may be disposed to face the plurality of second emission areas protruding from the other end of the first emission area.

An entirety of the emission area including the first emission area and the plurality of second emission areas may include at least two areas having different widths in the second direction.

An outer contour of the plurality of second emission areas may include a plurality of first straight portions extending in the second direction from one end of the first emission area, and a second straight portion connecting corresponding ones of the plurality of first straight portions and parallel to the first direction, wherein, an entire length of the second straight portion among the plurality of second emission areas disposed at one end of the first emission area may be 30% to 70% of an entire width of the first emission area in the first direction.

A maximum width of an entirety of the emission area including the first emission area and the plurality of second emission areas in the first direction may be greater than a maximum width thereof in the second direction.

The bank may be disposed between the plurality of second emission areas.

A display device according to another aspect of the present disclosure comprises a substrate on which a plurality of sub pixels each including an emission area is defined, a plurality of light emitting diodes disposed on the substrate in each of the plurality of sub pixels and including a first electrode, an emission layer, and a second electrode, a bank disposed on the substrate to cover an end of the first electrode and to define the emission area, and a plurality of optical members disposed on the plurality of light emitting diodes and having a bar shape extending in a first direction, wherein the emission area includes a plurality of protrusions and a plurality of recesses alternately disposed at each of opposite ends in a second direction.

The plurality of protrusions disposed at one end in the second direction and the plurality of protrusions disposed at the other end in the second direction may be disposed to face each other.

The emission area may include at least two areas having different widths in the second direction.

The plurality of protrusions disposed at one end in the second direction and the plurality of recesses disposed at the other end in the second direction may be disposed to face each other.

A width of the emission area in the second direction may be uniform.

An outer contour of the plurality of protrusions may include a first straight portion parallel to the first direction, an outer contour of the plurality of recesses includes a second straight portion parallel to the first direction, and at one end of the emission area, an entire length of the first straight portion may be equal to an entire length of the second straight portion.

A maximum width of the emission area in the first direction may be greater than a maximum width thereof in the second direction.

Although the embodiments of the present disclosure have been described in detail with reference to the accompanying drawings, the present disclosure is not limited thereto and may be embodied in many different forms without departing from the technical concept of the present disclosure. Therefore, the embodiments of the present disclosure are provided for illustrative purposes only but not intended to limit the technical concept of the present disclosure. The scope of the technical concept of the present disclosure is not limited thereto. Therefore, it should be understood that the above-described embodiments are illustrative in all aspects and do not limit the present disclosure. All the technical concepts in the equivalent scope of the present disclosure should be construed as falling within the scope of the present disclosure.

What is claimed is:

1. A display device, comprising:
a substrate;
a light emitting diode disposed on the substrate, the light emitting diode including a first electrode, an emission layer, and a second electrode;
a bank disposed on the substrate, the bank covering an end of the first electrode and defining an emission area; and
an optical member disposed on the light emitting diode, the optical member having a bar shape extending in a first direction,
wherein the emission area includes a first emission area extending in the first direction and a plurality of second emission areas protruding in a second direction from the first emission area.

2. The display device of claim 1, wherein a first subset of second emission areas of the plurality of second emission areas protruding from a first end of the first emission area is alternately disposed with a second subset of second emission areas of the plurality of second emission areas protruding from a second end of the first emission area.

3. The display device of claim 2, wherein a width of an entirety of the emission area including the first emission area and the plurality of second emission areas in the second direction is uniform.

4. The display device of claim 1, wherein a first subset of second emission areas of the plurality of second emission areas protruding from a first end of the first emission area is disposed to face a second subset of second emission areas of the plurality of second emission areas protruding from a second end of the first emission area.

5. The display device of claim 4, wherein an entirety of the emission area including the first emission area and the plurality of second emission areas includes at least two areas having different widths in the second direction.

6. The display device of claim 1, wherein an outer contour of the plurality of second emission areas includes a plurality of first straight portions extending in the second direction from a first end of the first emission area, and a second straight portion connecting corresponding ones of the plurality of first straight portions, the second straight portion being parallel to the first direction, and
wherein, an entire length of the second straight portion among the plurality of second emission areas disposed at an end of the first emission area is 30% to 70% of an entire width of the first emission area in the first direction.

7. The display device of claim 1, wherein a maximum width of an entirety of the emission area including the first emission area and the plurality of second emission areas in the first direction is greater than a maximum width of the entirety of the emission area in the second direction.

8. The display device of claim 1, wherein the bank is disposed between the plurality of second emission areas.

9. A display device, comprising:
a substrate on which a plurality of sub pixels are defined, each of the plurality of sub pixels including an emission area;
a plurality of light emitting diodes disposed on the substrate in each of the plurality of sub pixels, each of the plurality of light emitting diodes including a first electrode, an emission layer, and a second electrode;
a bank disposed on the substrate, the bank covering an end of the first electrode and defining the emission area; and
a plurality of optical members disposed on the plurality of light emitting diodes, each of the plurality of optical members having a bar shape extending in a first direction,
wherein the emission area includes a plurality of protrusions and a plurality of recesses alternately disposed at each of opposite ends of the emission area in a second direction.

10. The display device of claim 9, wherein the plurality of protrusions disposed at a first end of the emission area in the second direction and the plurality of protrusions disposed at a second end of the emission area in the second direction are disposed to face each other.

11. The display device of claim 10, wherein the emission area includes at least two areas having different widths in the second direction.

12. The display device of claim 9, wherein the plurality of protrusions disposed at a first end of the emission area in the second direction and the plurality of recesses disposed at a second end of the emission area in the second direction are disposed to face each other.

13. The display device of claim 12, wherein a width of the emission area in the second direction is uniform.

14. The display device of claim 9, wherein an outer contour of the plurality of protrusions includes a first straight portion parallel to the first direction,
wherein an outer contour of the plurality of recesses includes a second straight portion parallel to the first direction, and
wherein, at an end of the emission area, an entire length of the first straight portion is equal to an entire length of the second straight portion.

15. The display device of claim 9, wherein a maximum width of the emission area in the first direction is greater than a maximum width of the emission area in the second direction.
